(19) United States
(12) Patent Application Publication
(10) Pub. No.: US 2026/0231515 A1
(43) Pub. Date: Aug. 6, 2026

(54) SEMICONDUCTOR DEVICE

(71) Applicant: FUJI ELECTRIC CO., LTD., Kawasaki-shi (JP)

(72) Inventor: Taichi KARINO, Matsumoto-city (JP)

(73) Assignee: FUJI ELECTRIC CO., LTD., Kawasaki-shi (JP)

(21) Appl. No.: 19/635,353

(22) Filed: Mar. 31, 2026

Related U.S. Application Data
(63) Continuation of application No. PCT/JP2025/001248, filed on Jan. 17, 2025.

(30) Foreign Application Priority Data
Mar. 15, 2024 (JP) 2024-041114

(51) Int. Cl. H10D 84/00

(52) U.S. Cl. CPC H10D 84/206

(57) ABSTRACT

A semiconductor device includes: a semiconductor substrate; a lower-layer insulating film provided on a top surface side of the semiconductor substrate; a resistive layer provided on a top surface side of the lower-layer insulating film; an interlayer insulating film provided on a top surface side of the lower-layer insulating film and the resistive layer; a first front-surface electrode provided on a top surface side of the interlayer insulating film and electrically connected to one end of the resistive layer; a second front-surface electrode provided on the top surface side of the interlayer insulating film separately from the first front-surface electrode and electrically connected to another end of the resistive layer; and a rear-surface electrode provided on a bottom surface side of the semiconductor substrate, wherein a resistor implemented by the resistive layer and a first capacitor in which the lower-layer insulating film on a lower side of the resistive layer serves as a dielectric are connected in parallel to the first front-surface electrode.

### CROSS-REFERENCE TO RELATED APPLICATION

This application is a Continuation of PCT Application No. PCT/JP2025/001248, filed on Jan. 17, 2025, and claims the priority of Japanese Patent Application No. 2024-041114, filed on Mar. 15, 2024, the content of which is incorporated herein by reference.

### BACKGROUND OF THE INVENTION

### 1. Field of the Invention

The present disclosure relates to semiconductor devices.

### 2. Description of the Related Art

JP2020-098822A discloses a resistive element including a first external connection electrode provided on the top surface side of a chip, a second external connection electrode spaced apart from the first external connection electrode and provided in parallel with the first external connection electrode, and a protective film covering the first and second external connection electrodes and provided with first and second openings to partly expose the top surfaces of the first and second external connection electrodes, and further discloses that the resistive element may have a lateral structure.

JP2020-098884A discloses a resistive element including a lower-layer insulating film, a resistive layer provided on the lower-layer insulating-film, a resistive-layer protection element provided on the lower-layer insulating film in parallel with one of the side wall surfaces of the resistive layer and implemented by a tandem connection of a plurality of p-n junctions having alternate arrangements of n-type zones including n-type layers and p-type zones including p-type layers, an interlayer insulating film covering the resistive layer and the resistive-layer protection element, an external connection electrode provided on the interlayer insulating film and electrically connected to one of the terminals of the resistive layer and one of the terminals of the resistive-layer protection element, and another external connection electrode provided on the interlayer insulating film and electrically connected to the other terminal of the resistive layer and the other terminal of the resistive-layer protection element, and further discloses that the resistive element may have a lateral structure.

A case is presumed below, in which the resistive element as disclosed in JP2020-098822A or JP2020-098884A is used for a gate resistor of a switching element in a semiconductor module, such as an intelligent power module (IPM), including the switching element and a control circuit for controlling the switching element.

In such a case, since not only the gate resistor but also a capacitor are connected between a gate of the switching element and the control circuit, the resistive element as disclosed in JP2020-098822A or JP2020-098884A cannot be simply used for the gate resistor. Further, if the gate resistor and the capacitor are installed independently in different chips, a problem such as an increase in packaged area is inevitably caused.

### SUMMARY OF THE INVENTION

In view of the foregoing problems, the present disclosure provides a semiconductor device having a configuration capable of installing a resistor and a capacitor in a single chip.

An aspect of the present disclosure inheres in a semiconductor device including: semiconductor substrate; a lower-layer insulating film provided on a top surface side of the semiconductor substrate; a resistive layer provided on a top surface side of the lower-layer insulating film; an interlayer insulating film provided on a top surface side of the lower-layer insulating film and the resistive layer; a first front-surface electrode provided on a top surface side of the interlayer insulating film and electrically connected to one end of the resistive layer; a second front-surface electrode provided on the top surface side of the interlayer insulating film separately from the first front-surface electrode and electrically connected to another end of the resistive layer; and a rear-surface electrode provided on a bottom surface side of the semiconductor substrate, wherein a resistor implemented by the resistive layer and a first capacitor in which the lower-layer insulating film on a lower side of the resistive layer serves as a dielectric are connected in parallel to the first front-surface electrode.

### BRIEF DESCRIPTION OF THE DRAWINGS

FIG. 1 is a plan view illustrating an example of a semiconductor device according to a first embodiment;

FIG. 2 is a cross-sectional view taken along line A-A′ in FIG. 1;

FIG. 3 is a circuit diagram illustrating an equivalent circuit of the semiconductor device according to the first embodiment;

FIG. 4 is a circuit diagram illustrating an application example of the semiconductor device according to the first embodiment;

FIG. 5 is a cross-sectional view illustrating a semiconductor device of a comparative example;

FIG. 6 is a cross-sectional view illustrating the semiconductor device of the comparative example to which an equivalent circuit is added;

FIG. 7A is a circuit diagram illustrating the equivalent circuit of the semiconductor device of the comparative example;

FIG. 7B is another circuit diagram illustrating the equivalent circuit of the semiconductor device of the comparative example;

FIG. 8 is a graph showing a relation between an impedance and a frequency

FIG. 9 is a plan view illustrating an example of a semiconductor device according to a second embodiment;

FIG. 10 is a cross-sectional view taken along line A-A′ in FIG. 9;

FIG. 11 is a cross-sectional view taken along line B-B′ in FIG. 9;

FIG. 12 is a plan view illustrating an example of a semiconductor device according to a third embodiment;

FIG. 13 is a cross-sectional view taken along line A-A′ in FIG. 12; and

FIG. 14 is a cross-sectional view taken along line B-B′ in FIG. 12.

### DETAILED DESCRIPTION

With reference to the drawings, first to third embodiments of the present disclosure will be described below.

In the drawings, the same or similar elements are indicated by the same or similar reference numerals. The drawings are schematic, and it should be noted that the relationship between thickness and planar dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to third embodiments described below merely illustrate schematically devices and methods for specifying and giving shapes to the technical idea of the present disclosure, and the span of the technical idea is not limited to materials, shapes, structures, and relative positions of elements described herein.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

### FIRST EMBODIMENT

### Configuration of Semiconductor Device

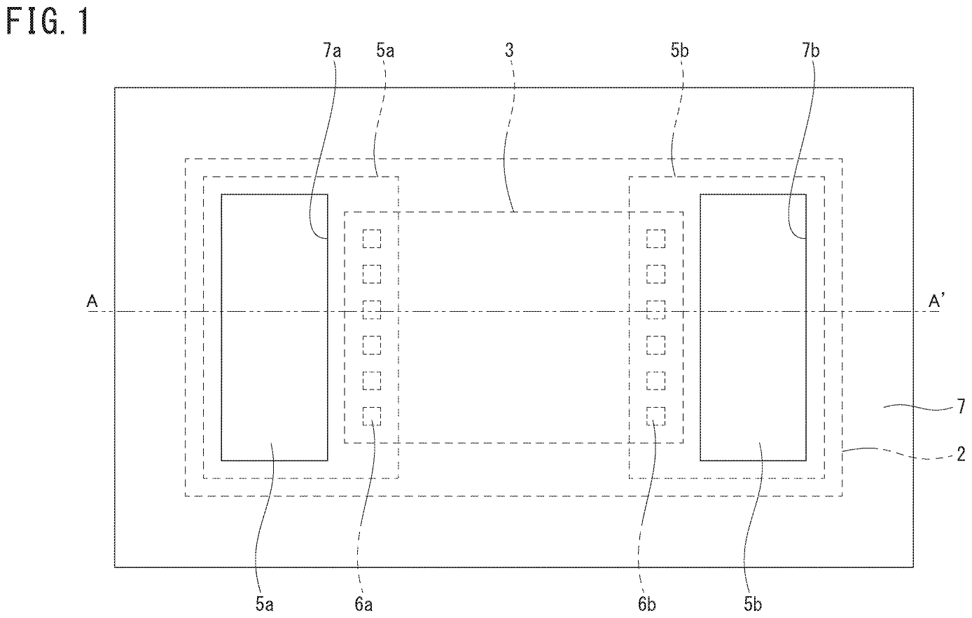

FIG. 1 is a planar layout illustrating a semiconductor device (a semiconductor chip) according to a first embodiment. FIG. 1 schematically indicates, by the broken lines, the outlines of a lower-layer insulating film 2, a resistive layer 3, a pair of front-surface electrodes (external connection electrodes) 5a and 5b, and contacts (contact plugs) 6a and 6b hidden under a passivation film 7.

The semiconductor device according to the first embodiment is a semiconductor chip having a substantially rectangular planar pattern defined such that a direction in which the front-surface electrode 5a, the resistive layer 3, and the front-surface electrode 5b are aligned (the right-left direction in FIG. 1) is a longitudinal direction, and a direction perpendicular to the direction in which the front-surface electrode 5a, the resistive layer 3, and the front-surface electrode 5b are aligned (the upper-lower direction in FIG. 1) is a short-side direction. A chip size of the semiconductor device according to the first embodiment is about 3.0 millimeters×2.5 millimeters, but is not limited to this case.

The lower-layer insulating film 2 has a rectangular planar pattern that has a longitudinal direction common to that of the semiconductor device according to the first embodiment (the right-left direction in FIG. 1). The resistive layer 3 located at an upper layer-level than the lower-layer insulating film 2 is provided on the inside of the outline of the lower-layer insulating film 2. The resistive layer 3 has a longitudinal direction common to that of the lower-layer insulating film 2 (the right-left direction in FIG. 1).

The respective front-surface electrodes 5a and 5b located at an upper layer-level than the resistive layer 3 are provided on the inside of the outline of the lower-layer insulating film 2 to interpose the resistive layer 3. The respective front-surface electrodes 5a and 5b have a substantially rectangular planar pattern in which a longitudinal direction is parallel to the short-side direction of the lower-layer insulating film 2 (the upper-lower direction in FIG. 1). The front-surface electrode 5a is electrically connected to the resistive layer 3 via the plural contacts 6a at a position overlapping with one end of the resistive layer 3 in the longitudinal direction located at a lower layer-level than the front-surface electrode 5a. The number and the arranged positions of the contacts 6a can be changed as appropriate. The front-surface electrode 5b is electrically connected to the resistive layer 3 via the plural contacts 6b at a position overlapping with the other end of the resistive layer 3 in the longitudinal direction located at a lower layer-level than the front-surface electrode 5b. The number and the arranged positions of the contacts 6b can be changed as appropriate.

The passivation film 7 is provided with openings 7a and 7b having a substantially rectangular shape. The opening 7a leads a part of the top surface of the front-surface electrode 5a to be exposed so as to serve as a pad region (an effective connection region) to which an external connection means such as a bonding wire can be connected. The opening 7b leads a part of the top surface of the front-surface electrode 5b to be exposed so as to serve as a pad region (an effective connection region) to which an external connection means such as a bonding wire can be connected.

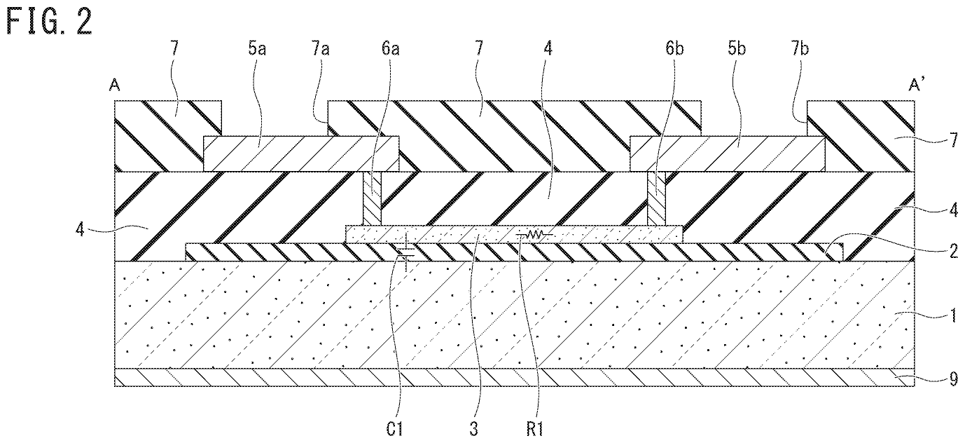

FIG. 2 is a cross-sectional view taken along line A-A′ illustrated in FIG. passing through the resistive layer 3 and the respective front-surface electrodes 5a and 5b. As illustrated in FIG. 2, the semiconductor device according to the first embodiment includes a semiconductor substrate 1, the lower-layer insulating film (a first insulating film) 2 provided on the top surface side of the semiconductor substrate 1, and the resistive layer 3 provided on the top surface side of the lower-layer insulating film 2.

A thickness of the semiconductor substrate 1 is set in a range of about 25 micrometers or greater and 450 micrometers or smaller, for example. The semiconductor substrate 1 as used herein can be a substrate having a low specific resistance, such as a silicon substrate, heavily doped with n-type impurities. The semiconductor substrate 1 may be a silicon substrate doped with p-type impurities instead, or may be a semiconductor substrate including material other than silicon.

The lower-layer insulating film 2 as used herein can be a silicon oxide fil (a SiO₂ film) or a silicon nitride film (a Si₃N₄ film), or a composite film including these films. In order to increase a capacitance value of a capacitance (also referred to below as a “capacitor” or a “condenser”) using the lower-layer insulating film 2 as a dielectric, material having higher relative permittivity than a SiO₂ film such as a Si₃N₄ film may be used for the lower-layer insulating film 2. Alternatively, the lower-layer insulating film 2 may be a film of local oxidation of silicon (a LOCOS film) formed by a LOCOS method in view of reliability and a longer life span of products. The lower-layer insulating film 2 as used herein may also be an insulating film (a TEOS film) obtained by a chemical vapor deposition (CVD) method using tetraethoxysilane (TEOS) gas of an organic silicon compound.

A thickness of the lower-layer insulating film 2 may be set in a range of about 15 nanometers or greater and 1000 nanometers or smaller, may be set in a range of about 15 nanometers or greater and 800 nanometers or smaller, may be set in a range of about 15 nanometers or greater and 500 nanometers or smaller, may be set in a range of about 15 nanometers or greater and 300 nanometers or smaller, or may be set in a range of about 15 nanometers or greater and 100 nanometers or smaller, for example. The thickness of the lower-layer insulating film 2 may also be set in a range of about 50 nanometers or greater and 1000 nanometers or smaller, set in a range of about 50 nanometers or greater and 800 nanometers or smaller, set in a range of about 50 nanometers or greater and 500 nanometers or smaller, set in a range of about 50 nanometers or greater and 300 nanometers or smaller, or set in a range of about 50 nanometers or greater and 100 nanometers or smaller.

The capacitance value of the capacitor using the lower-layer insulating film 2 as a dielectric can be increased, as the thickness of the lower-layer insulating film 2 is decreased. In order to increase the capacitance value of the capacitor, the thickness of the lower-layer insulating film 2 is preferably set to about 800 nanometers or smaller, more preferably set to about 500 nanometers or smaller, still more preferably set to about 300 nanometers or smaller, and still more preferably set to about 100 nanometers or smaller. When the semiconductor device according to the first embodiment is used for a gate resistor of an IGBT which is a switching element, the thickness of the lower-layer insulating film 2 is preferably set to about 15 nanometers or greater in order to ensure a gate voltage of about ±15 volts of the IGBT. The thickness of the lower-layer insulating film 2 is also preferably set to about 50 nanometers or greater when designed in the same manner as a gate insulating film in view of reliability and a longer life span of products.

The capacitance value of the capacitance using the lower-layer insulating film 2 as a dielectric can be increased, as the area of the lower-layer insulating film 2 immediately under the resistive layer 3 is increased. The area of the lower-layer insulating film 2 immediately under the resistive layer 3 is preferably set to about 1.5 mm 2 or greater in order to lead the capacitance value of the capacitor to be about 1 nF or greater.

A thickness of the resistive layer 3 is set in a range of about 400 nanometers or greater and 600 nanometers or smaller, for example. A sheet resistance of the resistive layer 3 is set in a range of about 100 Ω/sq or greater and 200 Ω/sq or smaller, for example. A resistance value of the resistive layer 3 can be regulated such that the thickness of the resistive layer 3, a width of the resistive layer 3 in the backward direction in the sheet of FIG. 2, a length of the resistive layer 3 in the right-left direction in FIG. 2, material included in the resistive layer 3, connection positions between the resistive layer 3 and the respective contacts 6a and 6b, and the like are adjusted.

The resistive layer 3 as used herein can include polysilicon (doped polysilicon) doped with n-type impurities or p-type impurities, for example. The doped polysilicon can be obtained such that n-type impurity ions or p-type impurity ions are implanted to polysilicon, or such that n-type impurities or p-type impurities are doped during the deposition of polysilicon by a chemical vapor deposition (CVD) method. The resistance value of the resistive layer 3 can be regulated such that a dose of the impurity ions, an acceleration voltage, a heat-treatment temperature, a heat-treatment time, and the like during the ion implantation to the resistive layer 3 are adjusted.

The resistive layer 3 is not limited to the doped polysilicon, but may be a film of a nitride of transition metal such as tantalum nitride (TaNₓ) or a stacked film of refractory metal films including chromium (Cr), nickel (Ni), and manganese (Mn) stacked in this order. Alternatively, the resistive layer 3 may be a thin film including a silver-palladium alloy (AgPd) or ruthenium oxide (RuO₂).

An interlayer insulating film (a second insulating film) 4 is provided on the top surface side of the lower-layer insulating film 2 and the resistive layer 3 so as to cover the lower-layer insulating film 2 and the resistive layer 3. A thickness of the interlayer insulating film 4 is set in a range of about one micrometer or greater and two micrometers or smaller, for example. The interlayer insulating film 4 as used herein can be a single-layer film such as a silicon oxide film (a SiO₂ film) without containing phosphorus (P) or boron (B), which is referred to as a non-doped silicate glass (NSG) film, a phosphosilicate glass film (a PSG film), a borosilicate glass film (a BSG film), a borophosphosilicate glass film (a BPSG film), or a silicon nitride film (a Si₃N₄ film), or can be a composite film including some of the above films selectively combined together.

The pair of the front-surface electrodes 5a and 5b are provided separately from each other on the top surface side of the interlayer insulating film 4. The front-surface electrode 5a is located over the lower-layer insulating film 2 to overlap in the depth direction with one end of the resistive layer 3 in the longitudinal direction. The front-surface electrode 5a is electrically connected to the one end of the resistive layer 3 in the longitudinal direction via the contacts 6a buried in the contact holes provided in the interlayer insulating film 4. The front-surface electrode 5b is located over the lower-layer insulating film 2 to overlap in the depth direction with the other end of the resistive layer 3 in the longitudinal direction. The front-surface electrode 5b is electrically connected to the other end of the resistive layer 3 in the longitudinal direction via the contacts 6b buried in the contact holes provided in the interlayer insulating film 4. The semiconductor device according to the first embodiment implements a resistor having a lateral structure in which the front-surface electrode 5a, the contacts 6a, the resistive layer 3, the contacts 6b, and the front-surface electrode 5b serve as a current path.

A thickness of the respective front-surface electrodes 5a and 5b are set in a range of about one micrometer or greater and five micrometers or smaller, for example. The front-surface electrodes 5a and 5b may each be a stacked film including titanium/titanium nitride (Ti/TiN) serving as barrier metal, aluminum/silicon (Al/Si), and TiN/Ti serving as an anti-reflection film. Instead of Al/Si, Al or an Al alloy such as Al/Si/copper (Cu) and Al/Cu may be used.

The passivation film 7 is provided on the top surface side of the interlayer insulating film 4 and the respective front-surface electrodes 5a and 5b. The passivation film 7 as used herein, which is not particularly limited as long as that is an insulating film, can be a composite film including a TEOS film, a Si₃N₄ film, and a polyimide film stacked together in this order. The passivation film 7 is provided with openings 7a and 7b. The front-surface electrodes 5a and 5b partly exposed to the openings 7a and 7b each serve as a pad region (an electrode pad) to which bonding wires (not illustrated) including aluminum (Al), for example, can be connected.

A rear-surface electrode (a third electrode) 9, which is an external connection terminal, is provided on the bottom surface side of the semiconductor substrate 1. The rear-surface electrode 9 can be a single-layer film including gold (Au), or a metal film including titanium (Ti), nickel (Ni), and Au stacked together in this order. The outermost layer of the rear-surface electrode 9 can include material that allows soldering. The semiconductor device according to the first embodiment is provided with a capacitor in which the resistive layer 3 serves as one electrode, the lower-layer insulating film 2 on the lower side of (immediately under) the resistive layer 3 serves as a dielectric (an insulator), and the semiconductor substrate 1 and the rear-surface electrode 9 each serve as the other electrode. FIG. 2 schematically indicates, by the circuit symbols, a resistor R1 implemented by the resistive layer 3 and a capacitor C1 implemented by the lower-layer insulating film 2 serving as a dielectric.

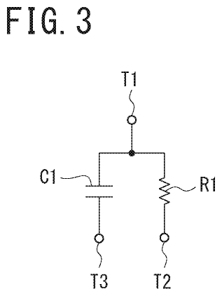

FIG. 3 is an equivalent circuit diagram of the semiconductor device according to the first embodiment illustrated in FIG. 1 and FIG. 2. One end of the resistor R1 and one end of the capacitor C1 are connected to a terminal T1 corresponding to the front-surface electrode 5a illustrated in FIG. 1 and FIG. 2. The other end of the resistor R1 is connected to a terminal T2 corresponding to the front-surface electrode 5b illustrated in FIG. 1 and FIG. 2. The other end of the capacitor C1 is connected to a terminal T3 corresponding to the rear-surface electrode 9 illustrated in FIG. 1 and FIG. 2.

### Method of Manufacturing Semiconductor Device

An example of a method of manufacturing the semiconductor device according to the first embodiment is described below with reference to FIG. 1 and FIG. 2. It should be understood that the manufacturing method described below is one of examples, and the semiconductor device according to this embodiment can be achieved by other various manufacturing methods including modified examples within the scope of the appended claims.

First, the semiconductor substrate 1 such as a silicon substrate heavily doped with n-type impurities is prepared. Next, the lower-layer insulating film 2 is formed on the top surface side of the semiconductor substrate 1 by a means such as a LOCOS method. The outer circumference of the lower-layer insulating film 2 is then partly and selectively removed as necessary by photolithography, dry etching, and the like.

Next, the resistive layer 3 is formed on the top surface side of each of t semiconductor substrate 1 and the lower-layer insulating film 2 by CVD method, ion implantation, and the like. The outer circumference of the resistive layer 3 is then partly and selectively removed by photolithography, dry etching, and the like.

Next, the interlayer insulating film 4 is deposited on the top surface side each of the lower-layer insulating film 2 and the resistive layer 3 by a CVD method and the like. The interlayer insulating film 4 is then party and selectively removed by photolithography, dry etching, and the like so as to open contact holes in the interlayer insulating film 4.

Next, a metal film is deposited so as to fill the contact holes by vacuum evaporation method or sputtering method, for example. The metal film is then partly and selectively removed by photolithography, dry etching, and the like so as to form the front-surface electrodes 5a and 5b on the top surface side of the interlayer insulating film 4.

Next, the passivation film 7 is formed on the top surface side of each of the interlayer insulating film 4 and the front-surface electrodes 5a and 5b. The passivation film 7 is then partly and selectively removed by photolithography, dry etching, and the like so as to provide the passivation film 7 with the openings 7a and 7b.

Subsequently, the bottom surface side of the semiconductor substrate 1 is ground as necessary so as to adjust the thickness of the semiconductor substrate 1. Thereafter, the rear-surface electrode 9 is formed on the bottom surface side of the semiconductor substrate 1 by vacuum evaporation method, sputtering method, or the like. A plurality of chip regions having the same configuration as the semiconductor device according to the first embodiment illustrated in FIG. 1 and FIG. 2 are formed in a matrix state in a single wafer, and the respective chip regions are then diced and divided into plural pieces each corresponding to the semiconductor device according to the first embodiment illustrated in FIG. 1 and FIG. 2.

### Application Example

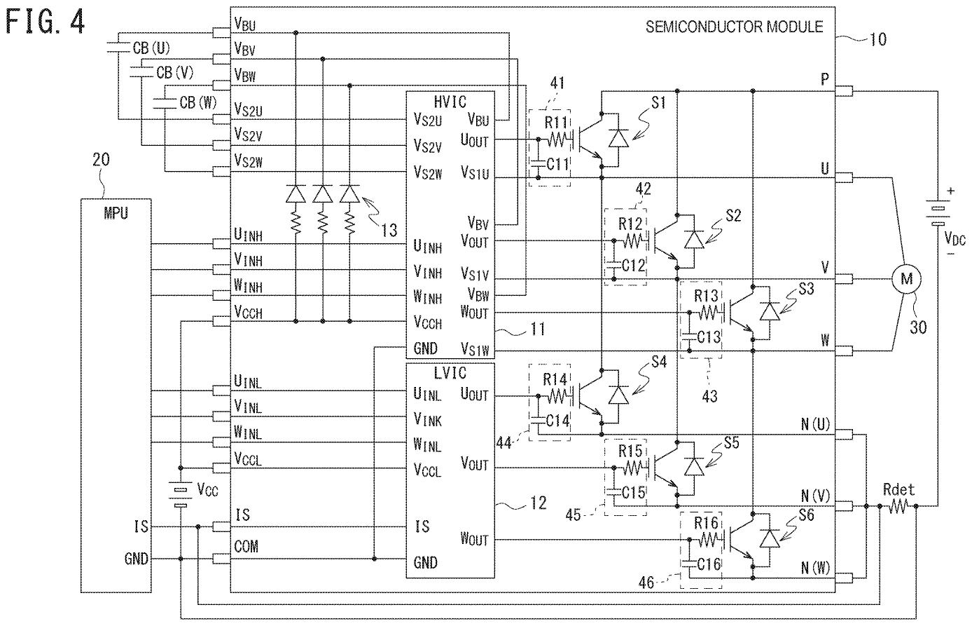

FIG. 4 is a diagram illustrating an example in which the configuration of the semiconductor device according to the first embodiment is applied to a semiconductor module 10 for driving a motor 30. The semiconductor module 10 can be an intelligent power module (IPM). The semiconductor module 10 includes switching elements S1 to S6, and a high-voltage integrated circuit (HVIC) 11 and a low-voltage integrated circuit (LVIC) 12 each serving as a control circuit (a driver IC) for controlling (driving) the switching elements S1 to S6. The switching elements S1 to S6 may each be an insulated gate bipolar transistor (IGBT) or a metal-oxide-semiconductor field-effect transistor (MOSFET), for example. The semiconductor module 10 is connected to the motor 30, a DC power source V_{DC}, a current-detection resistor Rdet, power-source capacitors CB (U), CB (V), and CB (W), a signal power source Vcc, and a controller 20.

The motor 30 is a three-phase motor connected to output terminals U, V, and W of three half-bridge circuits. A positive electrode of the DC power source V_{DC} is connected to a positive-electrode DC terminal P of the three half-bridge circuits. A negative electrode of the DC power source V_{DC} is connected to each of negative-electrode DC terminals N (U), N (V), and N (W) of the three half-bridge circuits via the current-detection resistor Rdet. The connections as described above allow the semiconductor module 10 to receive DC electric power from the DC power source V_{DC} via the positive-electrode DC terminal P and the negative-electrode DC terminals N (U), N (V), and N (W), so as to supply the electric power to the motor 30 via the output terminals U, V, and W.

The power-source capacitors CB (U), CB (V), and CB (W) are used as gate-driving power sources of the switching elements S1, S2, and S3 on the high-potential side. One of the paired terminals of the power-source capacitor CB (U) is connected to a gate power source terminal VBU, and the other terminal is connected to a reference potential terminal V_{S2U}. One of the paired terminals of the power-source capacitor CB (V) is connected to a gate power source terminal V_{BV}, and the other terminal is connected to a reference potential terminal V_{S2V}. One of the paired terminals of the power-source capacitor CB (W) is connected to a gate power source terminal V_{BW}, and the other terminal is connected to a reference potential terminal V_{S2W}.

A positive electrode of the signal power source Vcc is connected to each of a signal power-source terminal V_{CCH} and a signal power-source terminal V_{CCL}. A negative electrode of the signal power source Vcc is connected to each of a common terminal COM and a ground terminal GND of the controller 20. The signal power-source terminal V_{CCH} is connected to the respective gate power source terminals V_{BU}, V_{BV}, and V_{BW} via bootstrap diodes (BSD) 13 in a direction in which the anodes are connected to the signal power-source terminal V_{CCH}. The respective power-source capacitors CB (U), CB (V), and CB (W) are thus charged with the electric power from the signal power source Vcc.

The controller 20 is a microprocessing unit (MPU) for controlling pulse width modulation (PWM). The controller 20 is connected to signal input terminals U_{INH}, V_{INH}, and W_{INH}, the common terminal COM, signal input terminals U_{INL}, V_{INL}, and W_{INL}, and a current detection terminal IS.

The controller 20 outputs PWM signals input to the respective signal input terminals U_{INH}, V_{INH}, and W_{INH} and the respective signal input terminals U_{INL}, V_{INL}, and W_{INL}. The PWM signals input to the respective signal input terminals U_{INH}, V_{INH}, and W_{INH} are input to the HVIC 11. The PWM signals input to the respective signal input terminals U_{INL}, V_{INL}, and W_{INL} are input to the LVIC 12. The HVIC 11 and the LVIC 12 each output, from output terminals U_{OUT}, V_{OUT}, and W_{OUT}, signals for changing gate potentials of the corresponding switching elements S1 to S6 in accordance with the input PWM signals. This operation switches the ON/OFF states of the respective switching element S1 to S6 according to the PWM signals output from the controller 20.

The semiconductor module 10 has a function capable of detecting the current flowing through the respective phases of the three half-bridge circuits in accordance with the resistance value of the current-detection resistor Rdet so as to protect damage to the semiconductor module 10 if overcurrent is caused. A current-level signal according to a change in the resistance value of the current-detection resistor Rdet is input to the LVIC 12 via the current detection terminal IS and is further input to the controller 20. The LVIC 12 determines the presence or absence of overcurrent in accordance with a result of comparison between the corresponding current-level signal and a reference value, and executes current interruption in the LVIC 12 if overcurrent is caused. The controller 20 also determines the presence or absence of overcurrent in accordance with the result of the comparison between the corresponding current-level signal and the reference value, and executes current interruption in the HVIC 11 if overcurrent is caused.

A resistor R11 is connected between the output terminal U_{OUT} of the HVIC 11 and a gate of the switching element S1. A capacitor C11 is connected between the output terminal U and each of the output terminal U_{OUT} of the HVIC 11 and one end of the resistor R11. The resistor R11 and the capacitor C11 are installed in a single semiconductor chip 41 corresponding to the semiconductor device according to the first embodiment illustrated in FIG. 1 and FIG. 2. The resistor R11 serves as a gate resistor for decreasing oscillation during a short circuit in the switching element S1. The resistors R12 to R16 described below each have substantially the same functions as the resistor R11. The capacitor C11 has functions capable of protecting a rise of a gate voltage of the switching element S1 and controlling a turn-on time. The capacitors C12 to C16 described below each have substantially the same functions as the capacitor C11.

The resistor R12 is connected between the output terminal V_{OUT} of the HVIC 11 and a gate of the switching element S2. The capacitor C12 is connected between the output terminal V and each of the output terminal V_{OUT} of the HVIC 11 and one end of the resistor R12. The resistor R12 and the capacitor C12 are installed in a single semiconductor chip 42 corresponding to the semiconductor device according to the first embodiment illustrated in FIG. 1 and FIG. 2.

The resistor R13 is connected between the output terminal W_{OUT} of the HVIC 11 and a gate of the switching element S3. The capacitor C13 is connected between the output terminal W and each of the output terminal W_{OUT} of the HVIC 11 and one end of the resistor R13. The resistor R13 and the capacitor C13 are installed in a single semiconductor chip 43 corresponding to the semiconductor device according to the first embodiment illustrated in FIG. 1 and FIG. 2.

The resistor R14 is connected between the output terminal U_{OUT} of the LVIC 12 and a gate of the switching element S4. The capacitor C14 is connected between the negative-electrode DC terminal N (U) and each of the output terminal U_{OUT} of the LVIC 12 and one end of the resistor R14. The resistor R14 and the capacitor C14 are installed in a single semiconductor chip 44 corresponding to the semiconductor device according to the first embodiment illustrated in FIG. 1 and FIG. 2.

The resistor R15 is connected between the output terminal V_{OUT} of the LVIC 12 and a gate of the switching element S5. The capacitor C15 is connected between the negative-electrode DC terminal N (V) and each of the output terminal V_{OUT} of the LVIC 12 and one end of the resistor R15. The resistor R15 and the capacitor C15 are installed in a single semiconductor chip 45 corresponding to the semiconductor device according to the first embodiment illustrated in FIG. 1 and FIG. 2.

The resistor R16 is connected between the output terminal W_{OUT} of the LVIC 12 and a gate of the switching element S6. The capacitor C16 is connected between the negative-electrode DC terminal N (W) and each of the output terminal W_{OUT} of the LVIC 12 and one end of the resistor R16. The resistor R16 and the capacitor C16 are installed in a single semiconductor chip 46 corresponding to the semiconductor device according to the first embodiment illustrated in FIG. 1 and FIG. 2.

### Comparative Example

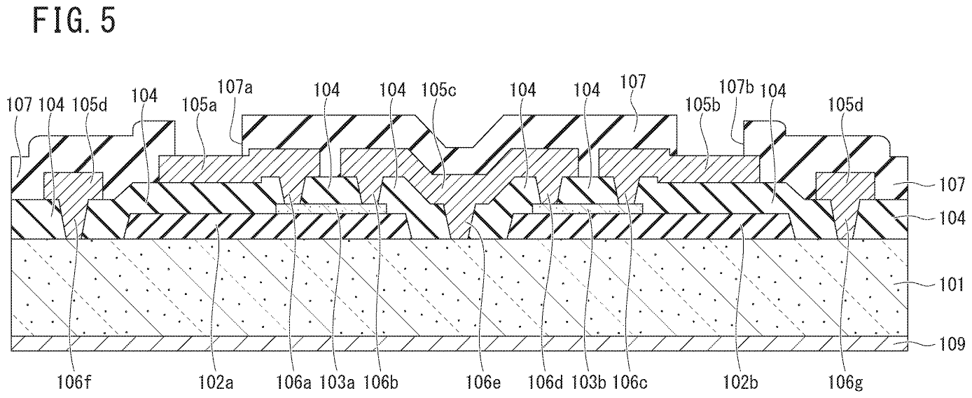

A semiconductor device of a comparative example is illustrated below with a resistive element having a vertical structure. The semiconductor device of the comparative example is used for a gate resistor for decreasing oscillation of an IGBT module having a large capacity. As illustrated in FIG. 5, the semiconductor device of the comparative example includes a semiconductor substrate 101, lower-layer insulating films 102a and 102b provided on the top surface side of the semiconductor substrate 101, and resistive layers 103a and 103b provided on the respective top surface sides of the lower-layer insulating films 102a and 102b. An interlayer insulating film 104 is provided on the top surface side of the lower-layer insulating films 102a and 102b and the resistive layers 103a and 103b.

Front-surface electrodes 105a and 105b and a relay wire 105c are provided on the top surface side of the interlayer insulating film 104. The front-surface electrode 105a is connected to the resistive layer 103a via contacts 106a. The front-surface electrode 105b is connected to the resistive layer 103b via contacts 106c. The relay wire 105c is connected to the resistive layer 103a via contacts 106b, is connected to the resistive layer 103b via contacts 106d, and is connected to the semiconductor substrate 101 via contacts 106e. A guard ring 105d is provided on the outside of the circumference of the respective front-surface electrodes 105a and 105b on the top surface side of the interlayer insulating film 104. The guard ring 105d is connected to the semiconductor substrate 101 via contacts 106f and 106g.

A passivation film 107 is provided on the top surface side of the front-surface electrodes 105a and 105b and the relay wire 105c. The passivation film 107 is provided with openings 107a and 107b. The openings 107a and 107b lead the front-surface electrodes 105a and 105b to be partly exposed to serve as pad regions. A rear-surface electrode 109 is provided on the bottom surface side of the semiconductor substrate 101. The semiconductor device of the comparative example is provided with a current path from the front-surface electrodes 105a and 105b toward the rear-surface electrode 109 through the resistive layers 103a and 103b, the relay wire 105c, and the semiconductor substrate 101.

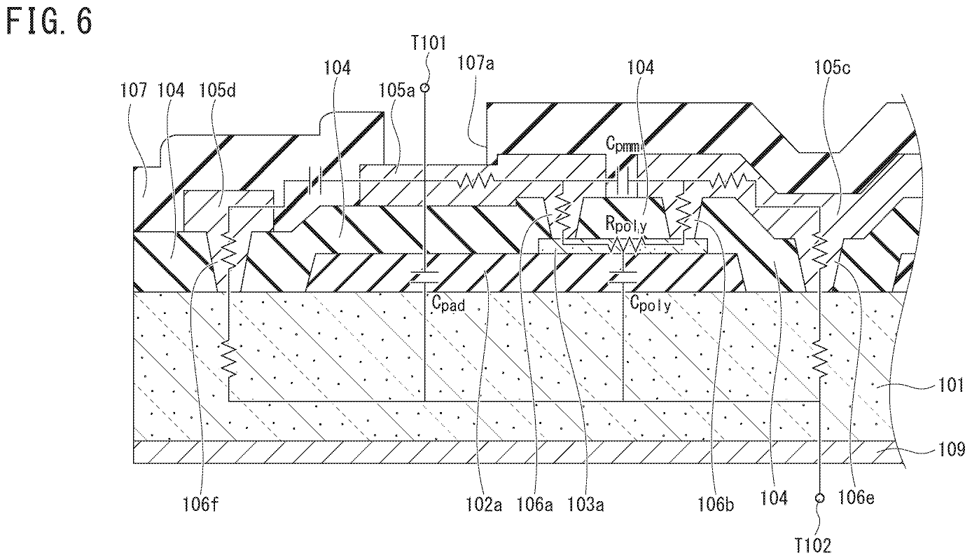

FIG. 6 is a view illustrating a cross-sectional structure on the left side of the semiconductor device of the comparative example illustrated in FIG. 5 on which an equivalent circuit is superposed. A terminal T101 is connected to the front-surface electrode 105a, and a terminal 102 is connected to the rear-surface electrode 109. A parasitic capacitor C_{pad}, in which the lower-layer insulating film 102a and the interlayer insulating film 104 each serve as a dielectric, is provided under the front-surface electrode 105a. A parasitic capacitor C_{poly}, in which the lower-layer insulating film 102a serves as a dielectric, is provided under the resistive layer 103a. A parasitic capacitor Cₚₘₘ, in which the passivation film 107 serves as a dielectric, interposed between the end of the front-surface electrode 105a and the end of the relay wire 105c is quite small and thus can be ignored.

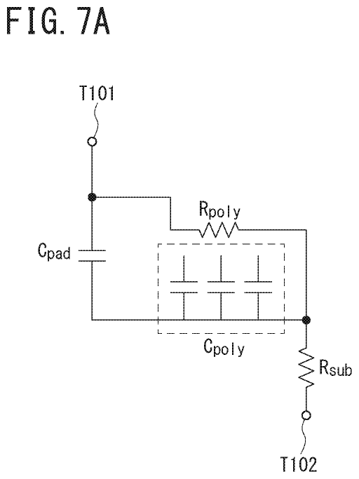

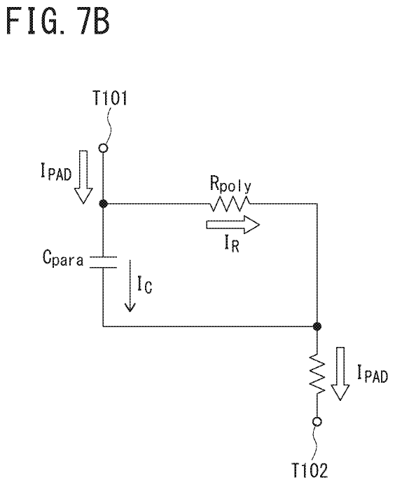

FIG. 7A is a circuit diagram corresponding to that illustrated in FIG. 6. The parasitic capacitor C_{poly} using the lower-layer insulating film 102a as a dielectric located under the resistive layer 103a is considered to be connected parallel to a resistor R_{poly} of the resistive layer 103a. FIG. 7B illustrates a case in which the parasitic capacitor C_{pad} and the parasitic capacitor C_{poly} are collectively defined as a parasitic capacitor Cₚₐᵣₐ. A current I_{PAD} flowing from the terminal T101 toward the terminal T102 is split into a current I_{R} flowing through the chip resistor R_{poly} and a current I_{C} flowing through the parasitic capacitor Cₚₐᵣₐ. If an impedance of the parasitic capacitor Cₚₐᵣₐ is lower than the chip resistor R_{poly}, the current IC flowing through the parasitic capacitor Cₚₐᵣₐ is led to be dominant, causing oscillation accordingly.

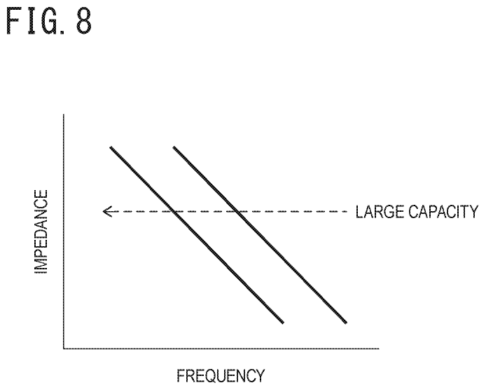

FIG. 8 is a graph showing a relation between the impedance of the parasitic capacitor Cₚₐᵣₐ and a frequency. The impedance of the parasitic capacitor Cₚₐᵣₐ is decreased, as the frequency is higher. The impedance of the parasitic capacitor Cₚₐᵣₐ is increased, as the capacitance value of the parasitic capacitor Cₚₐᵣₐ is lower. The semiconductor device of the comparative example thus needs to decrease the capacitance value of the parasitic capacitor Cₚₐᵣₐ and also needs to increase the thickness of the lower-layer insulating film 102 in order to avoid a decrease in the impedance of the parasitic capacitor C_{para.}

A case is presumed below, in which the semiconductor device of the comparative example is used not for the gate resistor for decreasing the oscillation of the large-capacity IGBT module but for the semiconductor module 10 including the HVIC 11 and the LVIC 12 each serving as the control circuit (the driver IC) illustrated in FIG. 4. In such a case, the semiconductor device of the comparative example cannot be simply used for the semiconductor module 10, since not only the gate resistors R11 to R16 but also the capacitors C11 to C16 are connected to the HVIC 11 and the LVIC 12.

In contrast, the semiconductor device according to the first embodiment has the configuration in which the resistor R1 and the capacitor C1 are installed in a single chip so that the resistor R1 and the capacitor C1 are connected in parallel to the terminal T1 corresponding to the front-surface electrode 5a, as illustrated in FIG. 1 to FIG. 3. This configuration enables each set of the gate resistors R11 to R16 and the capacitors C11 to C16 connected to the HVIC 11 and the LVIC 12 to be installed in the respective common semiconductor chips 41 to 46 each corresponding to the semiconductor device according to the first embodiment when used for the semiconductor module 10 including the HVIC 11 and the LVIC 12 each serving as the control circuit (the driver IC) illustrated in FIG. 4. A packaged size of the semiconductor module 10 thus can be decreased, as compared with a case in which the gate resistors R11 to R16 and the capacitors C11 to C16 are installed in different chips independently of each other. Further, this configuration only needs to change the semiconductor chips 41 to 46 including the gate resistors R11 to R16 and the capacitors C11 to C16 if the specifications of the switching elements S1 to S6 are required to be changed, so as to facilitate the handling to deal with such a problem.

### SECOND EMBODIMENT

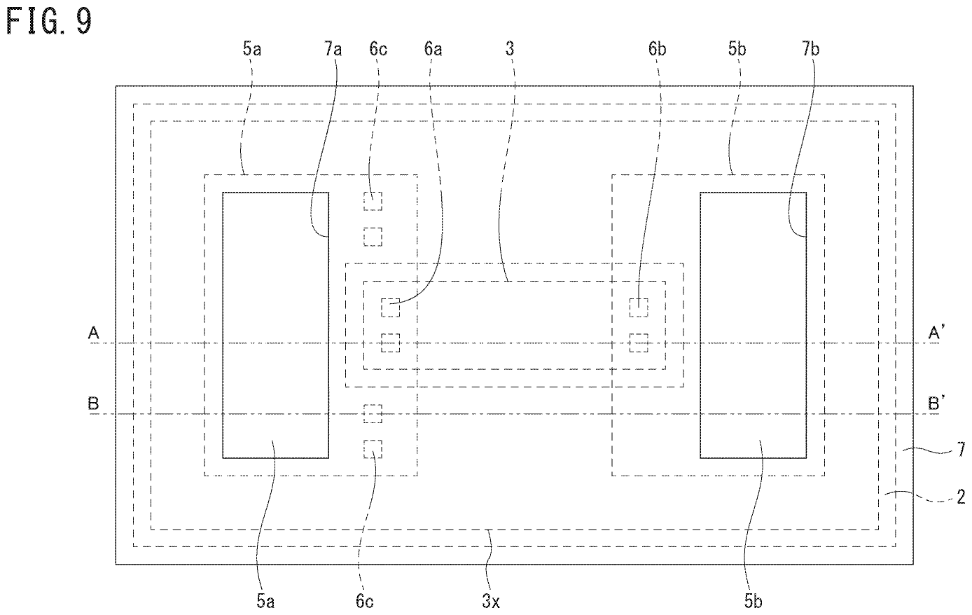

FIG. 9 is a plan view illustrating an example of a semiconductor device according to a second embodiment. FIG. 9 schematically indicates, by the broken lines, the lower-layer insulating film 2, the resistive layer 3, a conductive layer 3x, the front-surface electrodes 5a and 5b, and the contacts (contact plugs) 6a to 6c hidden under the passivation film 7. As illustrated in FIG. 9, the semiconductor device according to the second embodiment differs from the semiconductor device according to the first embodiment illustrated in FIG. 1 and FIG. 2 in further including the conductive layer 3x provided along the circumference of the resistive layer 3 at the same layer-level as the resistive layer 3.

As illustrated in FIG. 9, the conductive layer 3x is located on the inside the outline of the lower-layer insulating film 2, and has a loop-like (frame-like) planar pattern so as to surround the circumference of the resistive layer 3. The conductive layer 3x is not limited to the loop-like (frame-like) planar pattern, but may have a U-shaped planar pattern with a part of the loop-like (frame-like) shape cut off, for example. Alternatively, the conductive layer 3x may have a planar pattern including rectangular divided regions. The conductive layer 3x partly overlaps with the front-surface electrodes 5a and 5b located at an upper layer-level than the conductive layer 3x. The conductive layer 3x is electrically connected to the front-surface electrode 5a via the contacts 6c at a position overlapping with the front-surface electrode 5a. The number and the arranged positions of the contacts 6c can be changed as appropriate.

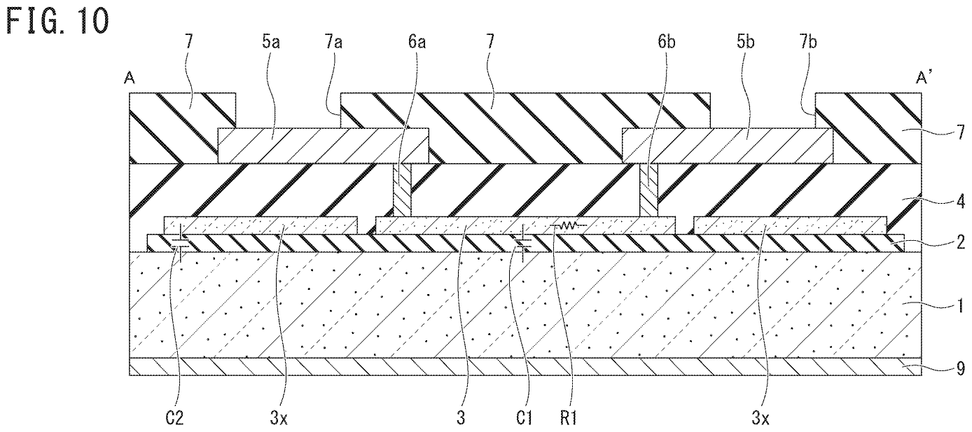

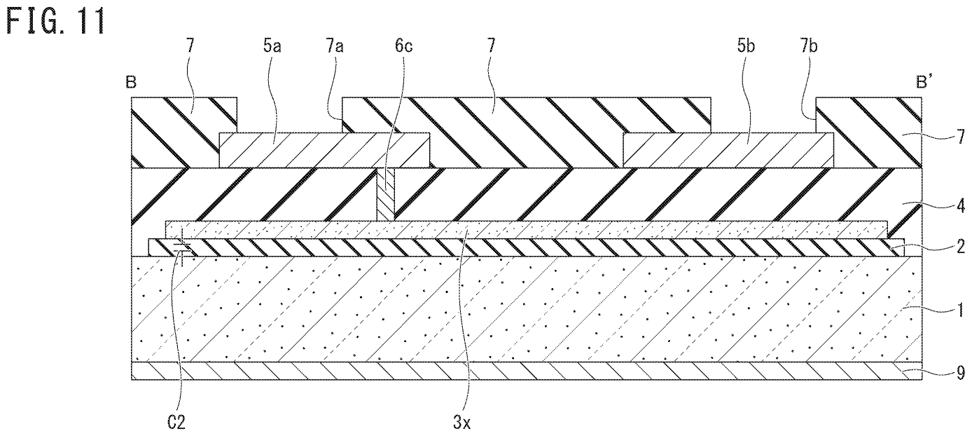

FIG. 10 is a cross-sectional view taken along line A-A′ illustrated in FIG. 9 passing through the resistive layer 3, the conductive layer 3x, and the front-surface electrodes 5a and 5b, and FIG. 11 is a cross-sectional view taken along line B-B′ illustrated in FIG. 9 passing through not the resistive layer 3 but the conductive layer 3x and the front-surface electrodes 5a and 5b. As illustrated in FIG. 10 and FIG. 11, the conductive layer 3x is provided separately from the resistive layer 3 on the top surface side of the lower-layer insulating film 2. The conductive layer 3x is located under the front-surface electrodes 5a and 5b. The conductive layer 3x includes the same material and has the same thickness as the resistive layer 3. The conductive layer 3x can be formed in the same step as the resistive layer 3.

The semiconductor device according to the second embodiment is provided with the capacitor C1 in which the resistive layer 3 serves as one electrode, the lower-layer insulating film 2 on the lower side of (immediately under) the resistive layer 3 serves as a dielectric (an insulator), and the semiconductor substrate 1 and the rear-surface electrode 9 each serve as the other electrode. The semiconductor device according to the second embodiment is further provided with a capacitor C2 in which the conductive layer 3x serves as one electrode, the lower-layer insulating film 2 on the lower side of (immediately under) the conductive layer 3x serves as a dielectric, and the semiconductor substrate 1 and the rear-surface electrode 9 each serve as the other electrode. The resistor R1, the capacitor C1, and the capacitor C2 are connected in parallel to the front-surface electrode 5a. The other structures of the semiconductor device according to the second embodiment are substantially the same as those of the semiconductor device according to the first embodiment illustrated in FIG. 1 and FIG. 2, and overlapping explanations are not repeated below.

The semiconductor device according to the second embodiment has the configuration that enables the resistor R1 and the respective capacitors C1 and C2 connected in parallel to the front-surface electrode 5a to be installed in a single chip. In addition, the capacitor C2, in which the lower-layer insulating film 2 immediately under the conductive layer 3x serves as a dielectric, is connected parallel to the capacitor C1, so as to increase the capacitance value more than that in the semiconductor device according to the first embodiment.

### THIRD EMBODIMENT

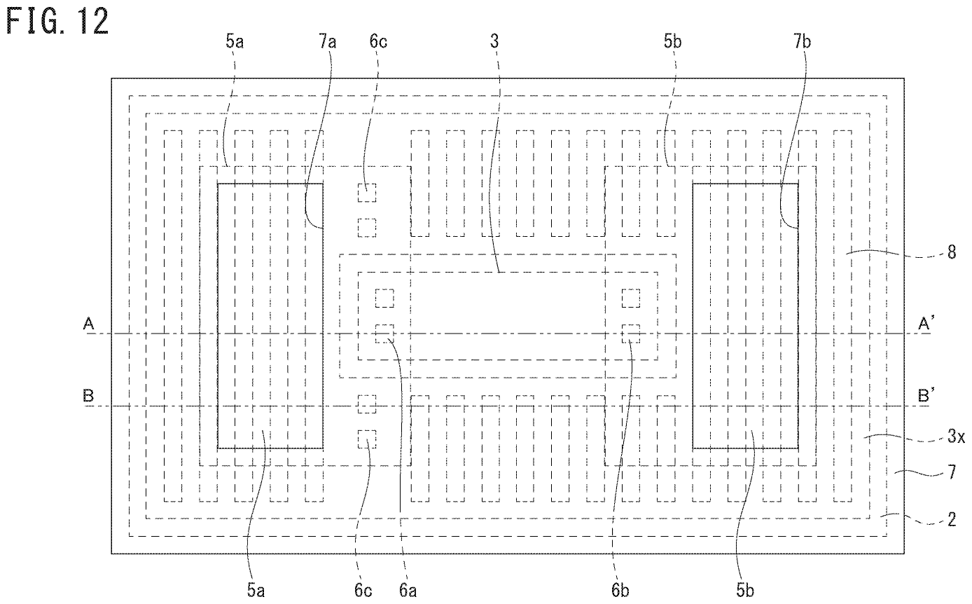

FIG. 12 is a plan view illustrating an example of a semiconductor device according to a third embodiment. FIG. 12 schematically indicates, by the broken lines, the lower-layer insulating film 2, the resistive layer 3, the conductive layer 3x, the front-surface electrodes 5a and 5b, the contacts (contact plugs) 6a to 6c, and trenches 8 hidden under the passivation film 7. As illustrated in FIG. 12, the semiconductor device according to the third embodiment has the same configuration as the semiconductor device according to the second embodiment illustrated in FIG. 9 to FIG. 11 in including the conductive layer 3x provided along the circumference of the resistive layer 3. The semiconductor device according to the third embodiment differs from the semiconductor device according to the second embodiment illustrated in FIG. 9 to FIG. 11 in further including the trenches 8 provided at a lower layer-level than the conductive layer 3x.

As illustrated in FIG. 12, the respective trenches 8 are located on the inside of the outline of the conductive layer 3x. The trenches 8 are provided separately from each other, and have a planar pattern formed into a plurality of stripes extending parallel to each other in the longitudinal direction of the front-surface electrodes 5a and 5b (in the upper-lower direction in FIG. 12). The pitch, the width, and the arranged positions of the trenches 8 on the inside of the outline of the conductive layer 3x can be determined as appropriate. The trenches 8 may have a planar pattern formed into a plurality of stripes extending parallel to each other in the short-side direction of the front-surface electrodes 5a and 5b (in the right-left direction in FIG. 12), or may have a planar pattern formed into dots, instead of stripes.

The trenches 8 are divided and provided opposed to each other so as to interpose the resistive layer 3 in the longitudinal direction of the front-surface electrodes 5a and 5b (in the upper-lower direction in FIG. 12). The trenches 8 are not provided around the contacts 6c in FIG. 12, but may be provided around the contacts 6c.

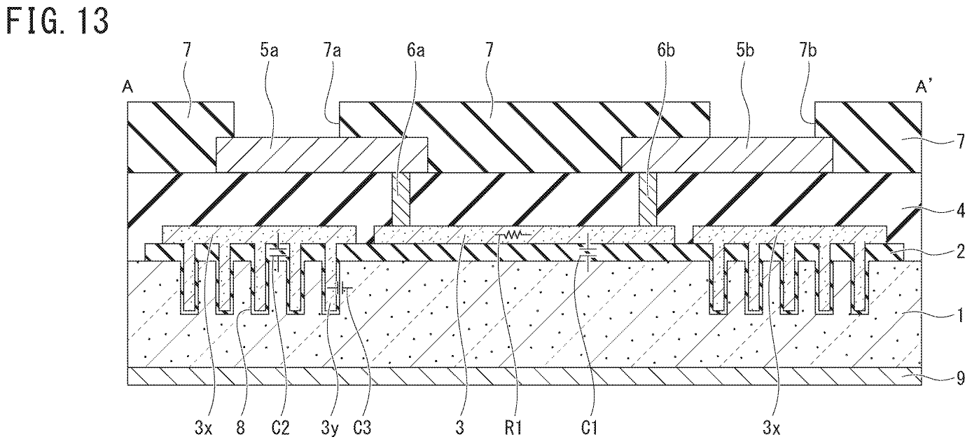

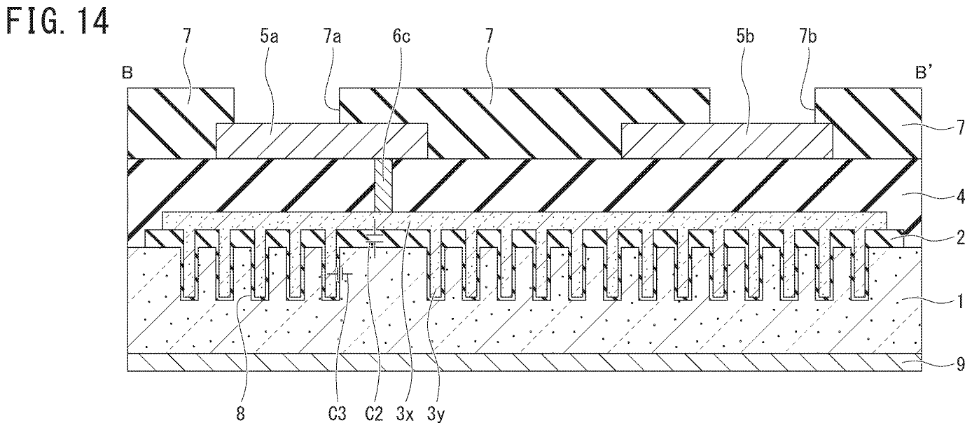

FIG. 13 is a cross-sectional view taken along line A-A′ illustrated in FIG. 12 passing through the resistive layer 3, the conductive layer 3x, and the front-surface electrodes 5a and 5b, and FIG. 14 is a cross-sectional view taken along line B-B′ illustrated in FIG. 12 passing through not the resistive layer 3 but the conductive layer 3x and the front-surface electrodes 5a and 5b. As illustrated in FIG. 13 and FIG. 14, the trenches 8 are provided toward the top surface side of the semiconductor substrate 1 and are dug from the top surface of the semiconductor substrate 1 in the depth direction. The lower-layer insulating film 2 is partly provided inside the respective trenches 8.

The thickness of the lower-layer insulating film 2 located on the top surface side of the semiconductor substrate 1 is greater than that located inside the respective trenches 8. The thickness of the lower-layer insulating film 2 located on the top surface side of the semiconductor substrate 1 may be the same as that located inside the respective trenches 8. The lower-layer insulating film 2 located inside the respective trenches 8 can ensure dielectric strength when including the same material as the gate insulating film of the switching element in the semiconductor module equipped with the semiconductor device according to the first embodiment and when having a thickness greater than or equal to that of the gate insulating film)

A buried layer (a conductive layer) 3y is buried inside the respective trenches 8 with the interlayer insulating film 2 interposed. The top surface of the buried layer 3y is in contact with the bottom surface of the conductive layer 3x. The material included in the buried layer 3y may be either the same as or different from that included in the resistive layer 3 and the conductive layer 3x. The buried layer 3y can be formed integrally with the conductive layer 3x in the same step as the resistive layer 3 and the conductive layer 3x.

The semiconductor device according to the third embodiment is provided with the capacitor C1 in which the lower-layer insulating film 2 immediately under the resistive layer 3 serves as a dielectric, and also provided with the capacitor C2 in which the lower-layer insulating film 2 immediately under the conductive layer 3x serves as a dielectric. A capacitor C3, in which the buried layer 3y buried in the trenches 8 serves as one electrode, the lower-layer insulating film 2 inside the respective trenches 8 serves as a dielectric (an insulator), and the semiconductor substrate 1 and the rear-surface electrode 9 each serve as the other electrode, is connected parallel to the respective capacitors C1 and C2. The other structures of the semiconductor device according to the third embodiment are substantially the same as those of the semiconductor device according to the first embodiment illustrated in FIG. 1 and FIG. 2 and the semiconductor device according to the second embodiment illustrated in FIG. 9 to FIG. 11, and overlapping explanations are not repeated below.

The semiconductor device according to the third embodiment has the configuration that enables the resistor R1 and the respective capacitors C1, C2, and C3 connected in parallel to the front-surface electrode 5a to be installed in a single chip. In addition, the capacitor C2, in which the lower-layer insulating film 2 immediately under the conductive layer 3x serves as a dielectric, and the capacitor C3, in which the lower-layer insulating film 2 inside the trenches 8 serves as a dielectric, are connected parallel to the capacitor C1, so as to further increase the capacitance value.

### OTHER EMBODIMENTS

As described above, the present disclosure has been described according to the first to third embodiments, but it should not be understood that the description and drawings implementing a portion of this disclosure limit the invention. Various alternative embodiments, examples, and operational techniques will be apparent to those skilled in the art from this disclosure.

For example, the respective semiconductor devices according to the first t third embodiments are used for the semiconductor module 10 illustrated in FIG. 4, but the configurations according to the respective embodiments can be applied to various kinds of integrated circuits (IC) including resistances and capacitors, instead of the semiconductor module 10.

In addition, the respective configurations disclosed in the first to third embodiments can be combined together as appropriate without contradiction with each other. As described above, the invention includes various embodiments and the like not described herein. Therefore, the scope of the present disclosure is defined only by subject matters recited in claims.

What is claimed is:

1. A semiconductor device comprising:
a semiconductor substrate;
a lower-layer insulating film provided on a top surface side of the semiconductor substrate;
a resistive layer provided on a top surface side of the lower-layer insulating film;
an interlayer insulating film provided on a top surface side of the lower-layer insulating film and the resistive layer;
a first front-surface electrode provided on a top surface side of the interlayer insulating film and electrically connected to one end of the resistive layer;
a second front-surface electrode provided on the top surface side of the interlayer insulating film separately from the first front-surface electrode and electrically connected to another end of the resistive layer; and
a rear-surface electrode provided on a bottom surface side of the semiconductor substrate,
wherein a resistor implemented by the resistive layer and a first capacitor which the lower-layer insulating film on a lower side of the resistive layer serves as a dielectric are connected in parallel to the first front-surface electrode.

2. The semiconductor device of claim 1, wherein the lower-layer insulating film has a thickness of 1000 nanometers or smaller.

3. The semiconductor device of claim 1, further comprising a conductive layer provided on the top surface side of the lower-layer insulating film separately from the resistive layer and electrically connected to the first front-surface electrode,
wherein a second capacitor in which the lower-layer insulating film on a lower side of the conductive layer serves as a dielectric is connected parallel to the first capacitor.

4. The semiconductor device of claim 3, wherein the conductive layer has a planar pattern surrounding a circumference of the resistive layer.

5. The semiconductor device of claim 3, further comprising a buried layer buried in a trench provided toward the top surface side of the semiconductor substrate with a part of the lower-layer insulating film interposed so as to be in contact with the conductive layer,
wherein a third capacitor in which the lower-layer insulating film inside t trench serves as a dielectric is connected parallel to the first capacitor and the second capacitor.

6. The semiconductor device of claim 5, wherein the trench has a plurality stripe-shaped planar patterns extending in one direction.

7. The semiconductor device of claim 6, wherein the trench has the planar patterns which are divided with the resistive layer interposed.

8. The semiconductor device of claim 5, wherein a thickness of the lower-layer insulating film located on the top surface side of the semiconductor substrate is greater than a thickness of the lower-layer insulating film located inside the trench.
